(19) United States
(12) Patent Application Publication
(10) Pub. No.: US 2011/0133249 A1
(43) Pub. Date: Jun. 9, 2011

(54) HIGH ELECTRON MOBILITY TRANSISTOR AND METHOD OF FORMING THE SAME

(75) Inventor: Ken SATO, Iruma-gun (JP)

(73) Assignee: SANKEN ELECTRIC CO., LTD., Saitama-ken (JP)

(21) Appl. No.: 13/026,887

(22) Filed: Feb. 14, 2011

Related U.S. Application Data
(62) Division of application No. 12/038,292, filed on Feb. 27, 2008.

(30) Foreign Application Priority Data
Feb. 27, 2007 (JP) 2007-046842
Jul. 30, 2007 (JP) 2007-197356

(51) Int. Cl. H01L 29/778

(52) U.S. Cl. 257/192; 257/E29.248

(57) ABSTRACT

A high electron mobility transistor includes first, second and third compound semiconductor layers. The second compound semiconductor layer has a first interface with the first compound semiconductor layer. The third compound semiconductor layer is disposed over the first compound semiconductor layer. The third compound semiconductor layer has at least one of lower crystallinity and relaxed crystal structure as compared to the second compound semiconductor layer. The gate electrode is disposed over the third compound semiconductor layer. Source and drain electrodes are disposed over the second compound semiconductor layer. The two-dimensional carrier gas layer is generated in the first compound semiconductor layer. The two-dimensional carrier gas layer is adjacent to the first interface. The two-dimensional carrier gas layer either is absent under the third compound semiconductor layer or is reduced in at least one of thickens and carrier gas concentration under the third compound semiconductor layer.

### BACKGROUND OF THE INVENTION

1. Field of the Invention

The present invention generally relates to a high electron mobility transistor and a method of forming the same.

Priorities are claimed on Japanese Patent Applications No. 2007-46842, filed Feb. 27, 2007, and No. 2007-197356, filed Jul. 30, 2007, the contents of which are incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

A high electron mobility transistor has a heterojunction structure. The heterojunction structure includes a heterojunction between undoped and doped compound semiconductor layers having different band gaps. A two-dimensional carrier gas layer including a two-dimensional electron gas layer is generated in the undoped compound semiconductor layer and in the vicinity of an interface between the undoped and doped compound semiconductor layers. The electrons in the two-dimensional electron gas layer can travel quickly without colliding with any impurities because the undoped compound semiconductor layer has no impurity. The undoped compound semiconductor layer allows electrons to travel quickly therein. The undoped compound semiconductor layer performs as an electron traveling layer. Quick travel of the electrons in the two-dimensional electron gas layer can improve the switching speed and sensitivity. The high electron mobility transistor will hereinafter be referred to as HEMT. The HEMT may also be called to as a heterojunction field effect transistor, HFET.

Nitride based compound semiconductors are greater in band gap energy than GaAs based compound semiconductors. Electron devices made of nitride based compound semiconductors are in general more superior in withstand voltage and efficiency than electron devices made of GaAs based compound semiconductors. Typical examples of the nitride based compound semiconductors may include, but are not limited to, GaN, InGaN, and AlInGaN.

An AlGaN/GaN heterostructure is one of the typical examples of the nitride based compound semiconductor heterostructure. Similarly to GaAs based device, the AlGaN/GaN heterostructure forms a two-dimensional electron gas layer which provides extremely high electron mobility. The AlGaN/GaN heterostructure causes a lattice strain on an interface between an AlGaN layer and a GaN layer. The lattice strain causes piezopolarization. Synergy of piezopolarization and spontaneous polarization may cause electron gas with extremely high concentration. The electron gas with extremely high concentration can realize an HEMT with much lower ON-resistance than that of silicon-based field effect transistors.

FIG. 7A is a fragmentary cross sectional elevation view illustrating a conventional nitride based compound semiconductor high electron mobility transistor. The conventional high electron mobility transistor, HEMT, has a heterojunction multilayered structure. The heterojunction multilayered structure includes an alumina single crystal substrate 1, a GaN buffer layer 2, an undoped GaN electron traveling layer 3, and an undoped AlGaN electron donor layer 4. The GaN buffer layer 2 extends over the alumina single crystal substrate 1. The undoped GaN electron traveling layer 3 extends over the GaN buffer layer 2. The undoped AlGaN electron donor layer 4 extends over the undoped GaN electron traveling layer 3. A heterojunction is formed on the interface between the undoped GaN electron traveling layer 3 and the undoped AlGaN electron donor layer 4. Namely, a heterojunction interface is present between the undoped GaN electron traveling layer 3 and the undoped AlGaN electron donor layer 4. The undoped AlGaN electron donor layer 4 is thinner than the undoped GaN electron traveling layer 3.

The conventional high electron mobility transistor, HEMT, also has a gate electrode 6, a source electrode 7 and a drain electrode 8. The gate electrode 6, the source electrode 7 and the drain electrode 8 are formed over the undoped AlGaN electron donor layer 4.

The undoped GaN electron traveling layer 3 is smaller in energy band gap than the undoped AlGaN electron donor layer 4.

The undoped GaN compound semiconductor is a binary crystal that exhibits spontaneous polarization and piezoeffect. The undoped AlGaN compound semiconductor is a ternary crystal that exhibits spontaneous polarization and piezoeffect. The undoped AlGaN compound semiconductor is different in lattice constant from the undoped GaN compound semiconductor.

The heterojunction interface between the undoped GaN electron traveling layer 3 and the undoped AlGaN electron donor layer 4 has the difference of lattice constant between undoped GaN compound semiconductor and the undoped AlGaN compound semiconductor. The difference of lattice constant at the heterojunction interface causes a crystal strain. The crystal strain causes piezoelectric effect to generate piezoelectric field. A spontaneous polarization is also caused by the different crystal lattices of the undoped GaN electron traveling layer 3 and the undoped AlGaN electron donor layer 4. The spontaneous polarization causes spontaneous polarization electric field. A synergy of the piezoelectric field and the spontaneous polarization electric field forms a two-dimensional electron gas layer 200 in the undoped GaN electron traveling layer 3, wherein the two-dimensional electron gas layer 200 is adjacent to the heterojunction interference.

The undoped AlGaN electron donor layer 4 performs to supply electrons to the undoped GaN electron traveling layer 3. A potential difference between the source and drain electrodes 7 and 8 causes that the supplied electrons can move or travel quickly in the two-dimensional electron gas layer 200 in the undoped GaN electron traveling layer 3. Applying a control voltage to the gate electrode 6 can form a depletion layer under the gate electrode 6. If the control voltage is at least a threshold, the depletion layer reaches and divides the two-dimensional electron gas layer 200 into two parts thereof, thereby controlling the electrons from moving and traveling in the two-dimensional electron gas layer 200.

As described above, the two-dimensional electron gas layer 200 is formed in the undoped GaN electron traveling layer 3, wherein the two-dimensional electron gas layer 200 is adjacent to the heterojunction interference. The piezopolarization and the spontaneous polarization are always present, which cause the electric field, thereby always generating the two-dimensional electron gas layer 200. The above-described conventional transistor is a normally-on-HEMT. The high electron mobility transistor having the heterojunction structure is a normally-on-transistor, wherein no application of the control voltage to the gate electrode 6 allows the electrons to move or travel quickly in the two-dimensional electron gas layer 200. Namely, no application of the control voltage to the gate electrode 6 allows a current flow between the source and drain electrodes 7 and 8. The high electron mobility transistor performs normally-on-operation. Application of the control voltage of at least threshold to the gate electrode 6 forms a depletion layer which reaches and divides the two-dimensional electron gas layer 200, thereby cutting off a current path between the source and drain electrodes 7 and 8. The high electron mobility transistor shown in FIG. 7A does not perform the normally-off operation. The high electron mobility transistor shown in FIG. 7A does not control the current flow between the source and drain electrodes 7 and 8 upon no control voltage application to the gate electrode 6.

In general, the semiconductor circuit of a silicon material has semiconductor devices which perform normally-off-operations. It is not easy to replace the normally-off semiconductor devices with the normally-on semiconductor devices.

FIG. 7B is a fragmentary cross sectional elevation view illustrating another conventional nitride based compound semiconductor high electron mobility transistor. The conventional nitride based compound semiconductor high electron mobility transistor, HEMT, perform normally-off operation. Japanese Unexamined Patent Application, First Publication, No. 2005-183733 discloses a normally-off HEMT.

The conventional normally-off high electron mobility transistor, HEMT, has another heterojunction multilayered structure. The heterojunction multilayered structure includes an alumina single crystal substrate 1, a GaN buffer layer 2, an undoped GaN electron traveling layer 3, and an undoped AlGaN electron donor layer 4. The undoped AlGaN electron donor layer 4 has a recess. The GaN buffer layer 2 extends over the alumina single crystal substrate 1. The undoped GaN electron traveling layer 3 extends over the GaN buffer layer 2. The undoped AlGaN electron donor layer 4 extends over the undoped GaN electron traveling layer 3. A heterojunction is formed on the interface between the undoped GaN electron traveling layer 3 and the undoped AlGaN electron donor layer 4. Namely, a heterojunction interface is present between the undoped GaN electron traveling layer 3 and the undoped AlGaN electron donor layer 4. The undoped AlGaN electron donor layer 4 has a recessed portion and a flat portion. The recessed portion is thinner than the flat portion. The undoped AlGaN electron donor layer 4 is thinner than the undoped GaN electron traveling layer 3. Both the recessed portion and the flat portion of the undoped AlGaN electron donor layer 4 are thinner than the undoped GaN electron traveling layer 3.

The conventional high electron mobility transistor, HEMT, also has a gate electrode 6, a source electrode 7 and a drain electrode 8. The gate electrode 6, the source electrode 7 and the drain electrode 8 are formed over the undoped AlGaN electron donor layer 4. The gate electrode 6 is disposed over the recessed portion of the undoped AlGaN electron donor layer 4. The conventional high electron mobility transistor, HEMT, has the recess gate structure.

The recess gate structure can be obtained by reducing the thickness of a portion of the undoped AlGaN electron donor layer 4. The recessed portion of the undoped AlGaN electron donor layer 4 is positioned under the gate electrode 6. Reduced thickness of the recessed portion of the undoped AlGaN electron donor layer 4 increases pinch-off voltage at the recessed portion. No application of the gate voltage to the gate electrode 6 causes partial disappearance of the two-dimensional electron gas layer under the recessed portion of the undoped AlGaN electron donor layer 4, while depletion layer being presented under the recessed portion of the undoped AlGaN electron donor layer 4. No current flow is caused between the source electrode 7 and the drain electrode 8 under no application of the gate voltage to the gate electrode 6. The transistor shown in FIG. 7B is a normally-off transistor.

The recessed portion of the undoped AlGaN electron donor layer 4 can be formed by selectively etching the undoped AlGaN electron donor layer 4. The undoped AlGaN electron donor layer 4 is so thin that etching the undoped AlGaN electron donor layer 4 provides damages to the undoped GaN electron traveling layer 3 that is adjacent to the recessed portion of the undoped AlGaN electron donor layer 4. The damages deteriorate the performance of the transistor.

In order to realize the normally-off operation, the etching process needs highly accurate control of the thickness of the recessed portion of the undoped AlGaN electron donor layer 4. The highly accurate control is atomic-level control. Atomic-level variation in thickness of the undoped AlGaN electron donor layer 4 can make it difficult for uniform control of the threshold voltage of the transistor. In some cases, the transistor can not satisfy the threshold regulation. In other cases, the transistor can not perform normally-off operation. As a result, the yield of the transistor is reduced.

In view of the above, it will be apparent to those skilled in the art from this disclosure that there exists a need for an improved high electron mobility transistor and a method of forming the same. This invention addresses this need in the art as well as other needs, which will become apparent to those skilled in the art from this disclosure.

### SUMMARY OF THE INVENTION

Accordingly, it is a primary object of the present invention to provide a high electron mobility transistor.

It is another object of the present invention to provide a high electron mobility transistor which controls threshold voltage at high accuracy.

It is a further object of the present invention to provide a high electron mobility transistor which has the normally-off characteristic.

It is a still further object of the present invention to provide a high electron mobility transistor which has a normally-on characteristic being similar to the normally-off characteristic.

It is yet a further object of the present invention to provide a high electron mobility transistor which can be formed easily as compared to the conventional high electron mobility transistor.

It is an additional object of the present invention to provide a method of forming a high electron mobility transistor.

It is another object of the present invention to provide a method of forming a high electron mobility transistor which controls threshold voltage at high accuracy.

It is still another object of the present invention to provide a method of forming a high electron mobility transistor which has the normally-off characteristic.

It is yet another object of the present invention to provide a method of forming a high electron mobility transistor which has a normally-on characteristic being similar to the normally-off characteristic.

It is an additional object of the present invention to provide a method of forming a high electron mobility transistor easily as compared to the conventional high electron mobility transistor.

In accordance with a first aspect of the present invention, a high electron mobility transistor may include, but is not limited to, first, second, third compound semiconductor layers, a gate electrode and a two-dimensional carrier gas layer. The first compound semiconductor layer has first and second faces. The second compound semiconductor layer may be disposed over the first compound semiconductor layer. The second compound semiconductor layer is closer to the first face than the second face. The third compound semiconductor layer may be disposed over the first compound semiconductor layer. The third compound semiconductor layer may have at least one of lower crystallinity and more relaxed crystal strain as compared to the second compound semiconductor layer. The gate electrode may be disposed over the third compound semiconductor layer. The two-dimensional carrier gas layer is present in the first compound semiconductor layer. The two-dimensional carrier gas layer is adjacent to the first face. The two-dimensional carrier gas layer either is absent under the third compound semiconductor layer or is reduced in at least one of thickens and carrier gas concentration under the third compound semiconductor layer.

In some cases, the second compound semiconductor layer may have a first heterojunction interface with the first compound semiconductor layer.

In some cases, the high electron mobility transistor may further include a fourth compound semiconductor layer. The fourth compound semiconductor layer may be interposed between the first and second compound semiconductor layers. The fourth compound semiconductor layer is greater in band gap than the first and second compound semiconductor layers.

In some cases, the third compound semiconductor layer may be lower in spontaneous polarization than the second compound semiconductor layer.

In some cases, the third compound semiconductor layer may be lower in piezopolarization with the first compound semiconductor layer than the second compound semiconductor layer.

In some cases, the third compound semiconductor layer may have a second heterojunction interface with the first compound semiconductor layer.

In some cases, the third compound semiconductor layer may be separated by the second compound semiconductor layer from the first compound semiconductor layer. The second compound semiconductor layer may have a first portion and a second portion, the first portion is positioned under the third compound semiconductor layer and over the first compound semiconductor layer. The first portion may be thinner than the second portion.

In some cases, the third compound semiconductor layer may be made of compound elements of the second compound semiconductor layer.

In some cases, the high electron mobility transistor may further include an insulating film between the gate electrode and the third compound semiconductor layer.

In some cases, the first and second compound semiconductor layers may include nitride based compound semiconductor. The third compound semiconductor layer may include the same compound semiconductor as the second compound semiconductor layer. The third compound semiconductor layer may have a thickness which is equal to or thicker than a few atomic layers.

In some cases, the third compound semiconductor layer may have a polycrystal structure or an amorphous structure.

In some cases, the high electron mobility transistor may further include source and drain electrodes disposed over the second compound semiconductor layer.

In accordance with a second aspect of the present invention, a high electron mobility transistor may include, but is not limited to, first, second and third compound semiconductor layers, a gate electrode, and a two-dimensional carrier gas layer. The first compound semiconductor layer has first and second faces. The second compound semiconductor layer may be disposed over the first compound semiconductor layer. The second compound semiconductor layer may be closer to the first face than the second face. The third compound semiconductor layer may be disposed over the first compound semiconductor layer. The third compound semiconductor layer may be lower in spontaneous polarization than the second compound semiconductor layer. The gate electrode may be disposed over the third compound semiconductor layer. The two-dimensional carrier gas layer may be present in the first compound semiconductor layer. The two-dimensional carrier gas layer may be adjacent to the first face. The two-dimensional carrier gas layer either may be absent under the third compound semiconductor layer or may be reduced in at least one of thickens and carrier gas concentration under the third compound semiconductor layer.

In some cases, the second compound semiconductor layer may have a first heterojunction interface with the first compound semiconductor layer.

In some cases, the high electron mobility transistor may further include a fourth compound semiconductor layer. The fourth compound semiconductor layer may be interposed between the first and second compound semiconductor layers. The fourth compound semiconductor layer may be greater in band gap than the first and second compound semiconductor layers.

In accordance with a third aspect of the present invention, a method of forming a high electron mobility transistor may include, but is not limited to, the following processes. A second compound semiconductor layer having a spontaneous polarization may be formed over a first compound semiconductor layer having first and second faces, so as to generate a two-dimensional carrier gas layer that is in the first compound semiconductor layer. The two-dimensional carrier gas layer is adjacent to the first face. The first face is closer to the second compound semiconductor layer than the second face. There is performed at least one of lowering the crystallinity of a first portion of the second compound semiconductor layer and relaxing the crystal strain of the first portion, to form a third compound semiconductor layer and to cause that the two-dimensional carrier gas layer reduces in at least one of the carrier gas concentration and the thickness under the third compound semiconductor layer or that the two-dimensional carrier gas layer is absent under the third compound semiconductor layer. A gate is formed over the third compound semiconductor layer.

In some cases, performing the at least one of lowering and relaxing may include selectively giving a physical energy to the second compound semiconductor layer.

In some cases, selectively giving the physical energy may include selectively annealing the second portion of the second compound semiconductor layer.

In some cases, selectively giving the physical energy may include carrying out at least one of an ion-implantation process and a plasma irradiation process to introduce ions into the first portion of the second compound semiconductor layer, thereby forming a third compound semiconductor layer.

In some cases, selectively giving the physical energy may include forming a thickness-controlling film over the first portion of the second compound semiconductor layer, and carrying out at least one of an ion-implantation process and a plasma irradiation process to introduce ions through the thickness-controlling film into the first portion of the second compound semiconductor layer, thereby forming a third compound semiconductor layer.

In some cases, the method may further include forming source and drain electrodes over the second compound semiconductor layer.

In some cases, the second compound semiconductor layer may have a first heterojunction interface with the first compound semiconductor layer.

In some cases, the method may further include forming a fourth compound semiconductor layer over the first compound semiconductor layer before the second compound semiconductor layer is formed over the fourth compound semiconductor layer. The fourth compound semiconductor layer may be greater in band gap than the first and second compound semiconductor layers.

In accordance with a fourth aspect of the present invention, a method of forming a high electron mobility transistor may include, but is not limited to, the following processes. A second compound semiconductor layer having a spontaneous polarization may be formed over a first compound semiconductor layer having first and second faces. The second compound semiconductor layer may have at least one of lower crystallinity and relaxed crystal structure as compared to the first compound semiconductor layer. The second compound semiconductor layer may have first and second portions. The second portion of the second compound semiconductor layer may be selectively annealed to crystallize the second portion, while allowing the first portion to have at least one of lower crystallinity and more relaxed crystal strain as compared to the second portion, thereby making the first portion into a third compound semiconductor layer, and generating a two-dimensional carrier gas layer that is in the first compound semiconductor layer. The two-dimensional carrier gas layer may be adjacent to the first face. The two-dimensional carrier gas layer either may be absent under the third compound semiconductor layer or may be reduced in at least one of thickens and carrier gas concentration under the third compound semiconductor layer. A gate may be formed over the third compound semiconductor layer.

In some cases, the method may further include forming a fifth compound semiconductor layer over the first compound semiconductor layer at a first temperature before forming the second compound semiconductor layer over the fifth compound semiconductor layer at a second temperature that is lower than the first temperature. The fifth compound semiconductor layer may be lattice-matched to the first compound semiconductor layer.

In some cases, the method may further include forming source and drain electrodes over the second compound semiconductor layer.

In some cases, the second compound semiconductor layer may have a first heterojunction interface with the first compound semiconductor layer.

In some cases, the method may further include forming a fifth compound semiconductor layer over the first compound semiconductor layer before the second compound semiconductor layer is formed over the fourth compound semiconductor layer. The fourth compound semiconductor layer may be greater in band gap than the first and second compound semiconductor layers.

In accordance with a fifth aspect of the present invention, a method of forming a high electron mobility transistor may include, but is not limited to, the following processes. A compound semiconductor layer is formed over a first compound semiconductor at a second temperature that is lower than a first temperature at which the first compound semiconductor is formed. The compound semiconductor layer has first and second portions. The second portion of the compound semiconductor layer is selectively annealed, thereby making the second portion into a second compound semiconductor layer and also making the first portion into a third compound semiconductor layer. The first compound semiconductor layer has a two-dimensional carrier gas layer close to the compound semiconductor layer. The two-dimensional carrier gas layer either is absent under the third compound semiconductor layer or is reduced in at least one of thickens and carrier gas concentration under the third compound semiconductor layer. A gate is formed over the third compound semiconductor layer.

In accordance with a sixth aspect of the present invention, a method of forming a high electron mobility transistor may include, but is not limited to, the following processes. A second compound semiconductor layer is formed over a first compound semiconductor. The second compound semiconductor layer has first and second portions. At least one of an ion-implantation process and a plasma irradiation process is carried out to introduce ions into the first portion of the second compound semiconductor layer, thereby forming a third compound semiconductor layer, so that the first compound semiconductor layer has a two-dimensional carrier gas layer close to the compound semiconductor layer, the two-dimensional carrier gas layer either is absent under the third compound semiconductor layer or is reduced in at least one of thickens and carrier gas concentration under the third compound semiconductor layer. A gate is formed over the third compound semiconductor layer.

These and other objects, features, aspects, and advantages of the present invention will become apparent to those skilled in the art from the following detailed descriptions taken in conjunction with the accompanying drawings, illustrating the embodiments of the present invention.

The third compound semiconductor layer may have at least one of lower crystallinity and relaxed crystal structure as compared to the second compound semiconductor layer. Thus, the third compound semiconductor layer is lower in spontaneous polarization than the second compound semiconductor layer. The piezopolarization between the first and third compound semiconductor layers is lower than the piezopolarization between the first and second compound semiconductor layers. The electric field may depend upon either or both the spontaneous polarization and piezopolarization. The electric field between the first and third compound semiconductor layers is lower than the electric field between the second and third compound semiconductor layers. The two-dimensional carrier gas layer may either be absent under the third compound semiconductor layer or be reduced in at least one of thickens and carrier gas concentration under the third compound semiconductor layer. The gate electrode may be disposed over the third compound semiconductor layer. The high electron mobility transistor may perform normally-off operation or normally-on operation that is similar to the normally-off operation.

### BRIEF DESCRIPTION OF THE DRAWINGS

Referring now to the attached drawings which form a part of this original disclosure:

FIG. 1 is a fragmentary cross sectional elevation view illustrating a high electron mobility transistor in accordance with a first embodiment of the present invention;

FIG. 2 is a fragmentary cross sectional elevation view illustrating the heterojunction structure between the first and second compound semiconductor layers;

FIG. 3 is a fragmentary cross sectional elevation view illustrating a high electron mobility transistor in a modification to the first embodiment of the present invention;

FIGS. 4A through 4E are fragmentary cross sectional elevation views illustrating sequential steps involved in a method of forming the high electron mobility transistor of FIG. 3;

FIGS. 5A through 5D are fragmentary cross sectional elevation views illustrating sequential steps involved in another method of forming a modified high electron mobility transistor, wherein the sequential steps are subsequent to the step shown in FIG. 4B;

FIG. 6 is a fragmentary cross sectional elevation view illustrating a high electron mobility transistor in another modification to the first embodiment of the present invention;

FIG. 7A is a fragmentary cross sectional elevation view illustrating a conventional nitride based compound semiconductor high electron mobility transistor;

FIG. 7B is a fragmentary cross sectional elevation view illustrating another conventional nitride based compound semiconductor high electron mobility transistor;

FIGS. 8A through 8C are fragmentary cross sectional elevation views illustrating sequential steps involved in a method of forming the high electron mobility transistor shown in FIG. 1;

FIGS. 9A through 9C are fragmentary cross sectional elevation views illustrating sequential steps involved in another method of forming the high electron mobility transistor shown in FIG. 3; and

FIG. 10 is a fragmentary cross sectional elevation view illustrating a high electron mobility transistor in accordance with a further modification to the first embodiment of the present invention.

### DETAILED DESCRIPTION OF THE INVENTION

A high electron mobility transistor may include first and second compound semiconductor layers which have a heterojunction. The second compound semiconductor layer includes a crystallinity-lowered portion which is lower in crystallinity than the other portion of the second compound semiconductor layer. The crystallinity-lowered portion may be a third compound semiconductor layer. The third compound semiconductor layer of the crystallinity-lowered portion is positioned under a gate electrode. The crystallinity-lowered portion can be obtained by lowering the crystallinity of a portion of the second compound semiconductor layer. Lowering the crystallinity may be realized by, but not limited to, an ion-implantation process and a plasma irradiation process. The third compound semiconductor layer is lower in the crystallinity than the second compound semiconductor layer. Spontaneous polarization depends on the crystallinity. The third compound semiconductor layer is lower in spontaneous polarization than the second compound semiconductor layer. The third compound semiconductor layer is lower in piezopolarization than the second compound semiconductor layer. The concentration of the two-dimensional electron gas depends on the spontaneous polarization and the piezopolarization.

A first interface is present between the first and second compound semiconductor layers. A second interface is present between the first and third compound semiconductor layers. A first two-dimensional electron gas layer is formed adjacent to and along the first interface between the first and second compound semiconductor layers. In some cases, no two-dimensional electron gas layer may be formed adjacent to and along the second interface between the first and third compound semiconductor layers. In other cases, a second two-dimensional electron gas layer may be formed adjacent to and along the second interface between the first and third compound semiconductor layers. The third compound semiconductor layer is lower in spontaneous polarization and piezopolarization than the second compound semiconductor layer. The concentration of the two-dimensional electron gas depends on the spontaneous polarization and the piezopolarization. The second two-dimensional electron gas layer may be lower in concentration than the first two-dimensional electron gas layer. The second two-dimensional electron gas layer may be smaller in thickness than the first two-dimensional electron gas layer. The thickness of the two-dimensional electron gas layer is a dimension thereof that is defined in a direction vertical to the first and second interferences.

The crystal strain of the third compound semiconductor layer is caused by the difference in the crystal structure between the first and third compound semiconductor layers. The lattice-pitch of the third compound semiconductor layer is changed by the difference in lattice pitch between the first and third compound semiconductor layers. The crystal strain of the second compound semiconductor layer is caused by the difference in the crystal structure between the first and second compound semiconductor layers. The lattice-pitch of the second compound semiconductor layer is changed by the difference in lattice pitch between the first and second compound semiconductor layers. The crystal strain of the third compound semiconductor layer can be relaxed by ion-implantation or plasma irradiation to the third compound semiconductor layer.

Ion-implantation or plasma irradiation to the third compound semiconductor layer relaxes the strain of the crystal structure of the third compound semiconductor layer so that the strained crystal structure thereof is returned to the original crystal structure that has the original lattice-pitch. The original crystal structure has no strain or relaxed strain. The relaxed strain of the crystal structure of the third compound semiconductor layer decreases the piezopolarization of the third compound semiconductor layer so that the third compound semiconductor layer is lower in piezopolarization than the second compound semiconductor layer. Reduced piezopolarization may, in some cases, cause no two-dimensional electron gas layer or a second two-dimensional electron gas layer adjacent to and along the second interface between the first and third compound semiconductor layers. The second two-dimensional electron gas layer is lower in concentration than the first two-dimensional electron gas layer that is formed adjacent to and along the first interface between the first and second compound semiconductor layers.

No two-dimensional electron gas layer permits the high electron mobility transistor to perform the normally-off operation. The second two-dimensional electron gas layer permits the high electron mobility transistor to perform normally-on operation that is similar to the normally-off operation.

In the above descriptions, the first compound semiconductor layer may typically be an electron traveling layer, and the second semiconductor layer may typically be an electron donor layer.

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

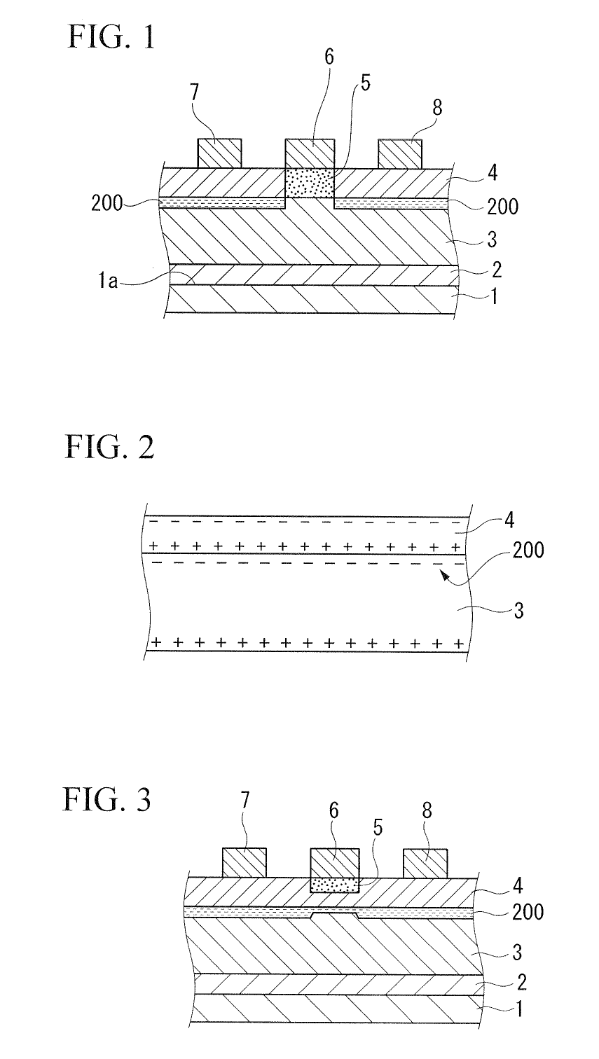

FIG. 1 is a fragmentary cross sectional elevation view illustrating a high electron mobility transistor in accordance with a first embodiment of the present invention. A high electron mobility transistor is formed over a substrate 1. The high electron mobility transistor has a multi-layered structure that extends over the substrate 1. The multi-layered structure may include, but is not limited to, a buffer layer 2, an electron traveling layer 3, and an electron donor layer 4. The buffer layer 2 extends over the substrate 1. The electron traveling layer 3 extends over the buffer layer 2. The electron donor layer 4 extends over the electron traveling layer 3.

The substrate 1 may be realized by a silicon-based substrate, a compound semiconductor substrate, an insulating substrate. Typical examples of the material of the silicon-based substrate may include, but are not limited to, silicon (Si), and silicon carbide (SiC). Typical examples of the material of the compound semiconductor substrate may include, but are not limited to, gallium arsenide (GaAs) and gallium nitride (GaN). A typical example of the material of the insulating substrate may include, but are not limited to, a ceramic such as alumina.

In some cases, the substrate 1 may have a thickness in the range of about 350 micrometers to about 1000 micrometers. The substrate 1 may be made of single crystal silicon that is smaller in linear expansion coefficient than the buffer layer 2, the electron traveling layer 3 and the electron donor layer 4. The substrate 1 of single crystal silicon is different in lattice constant from the buffer layer 2, the electron traveling layer 3 and the electron donor layer 4.

The buffer layer 2 is disposed between the substrate 1 of single crystal silicon and the electron traveling layer 3 of compound semiconductor. The buffer layer 2 relaxes the lattice-strain that is caused by the lattice-mismatch between the substrate 1 of single crystal silicon and the electron traveling layer 3 of compound semiconductor. In some cases, the buffer layer 2 can be realized by a known low temperature buffer layer. In some cases, the buffer layer 2 can be realized by alternating stacks of an MN layer and a GaN layer.

The electron traveling layer 3 performs as a first compound semiconductor layer. The electron traveling layer 3 extends over the buffer layer 2. A two-dimensional electron gas layer 200 is formed in the electron traveling layer 3. The electron traveling layer 3 may be made of an intrinsic compound semiconductor. In some cases, the electron traveling layer 3 may be made of an undoped compound semiconductor that has spontaneous polarization. In other cases, the electron traveling layer 3 may be made of another undoped compound semiconductor free of any spontaneous polarization. Typically, the electron traveling layer 3 may be made of an undoped GaN, for example, intrinsic GaN. In some cases, the thickness of the electron traveling layer 3 may be ranged from 1 micrometer to 3 micrometers.

The electron donor layer 4 performs as a second compound semiconductor layer. The electron donor layer 4 extends over the electron traveling layer 3. A first interface is formed between the electron traveling layer 3 that performs as the first compound semiconductor layer and the electron donor layer 4 that performs as the second compound semiconductor layer. The electron donor layer 4 as the second compound semiconductor layer has a wider band gap than that of the electron traveling layer 3 as the first compound semiconductor layer. The electron donor layer 4 as the second compound semiconductor layer is made of a compound semiconductor that has spontaneous polarization. A typical example of the compound semiconductor of the electron donor layer 4 may be, but is not limited to, a nitride-based compound semiconductor such as AlₓIn_{y}Ga_{1-x-y}N (0≦x≦1, 0≦y≦1, 0≦x+y≦1). Preferably, the compound semiconductor of the electron donor layer 4 may be AlₓGa₁₋ₓN (0.2≦x≦0.4). More preferably, the compound semiconductor of the electron donor layer 4 may be Al_{0.3}Ga_{0.7}N.

In some cases, the thickness of the electron donor layer 4 as the second compound layer may be ranged from 5 nanometers to 50 nanometers. Preferably, the thickness of the electron donor layer 4 may be about 20 nanometers.

FIG. 2 is a fragmentary cross sectional elevation view illustrating the heterojunction structure between the first and second compound semiconductor layers 3 and 4. A heterojunction is formed between the first and second compound semiconductor layers 3 and 4. A lattice-mismatch is present between the first and second compound semiconductor layers 3 and 4. The first compound semiconductor layer 3 has a piezopolarization that is caused by the lattice-mismatch between the first and second compound semiconductor layers 3 and 4. The second compound semiconductor layer 4 has a spontaneous polarization due to the crystal structure thereof. The piezopolarization and the spontaneous polarization generate an electric field in a direction vertical to the interface between the first and second compound semiconductor layers 3 and 4. The direction of the electric field is from the first compound semiconductor layer 3 to the second compound semiconductor layer 4. The electric field caused by the piezopolarization and the spontaneous polarization generates a two-dimensional electron gas layer 200 in the first compound semiconductor layer 3 performing as the electron traveling layer, wherein the two-dimensional electron gas layer 200 is adjacent to the interface with the second compound semiconductor layer 4 performing as the electron donor layer.

In some cases, the second compound semiconductor layer 4 may not include any impurity. In other cases, the second compound semiconductor layer 4 may include an n-type impurity. In some cases, the second compound semiconductor layer 4 may be made of a compound semiconductor that is different in lattice constant from the compound semiconductor of the first compound semiconductor layer 3. In other cases, the second compound semiconductor layer 4 may be made of a nitride based compound semiconductor that has the same lattice constant as that of the compound semiconductor of the first compound semiconductor layer 3. The AlInN based compound semiconductor has a spontaneous polarization that is greater than its piezopolarization. Deteriorating crystallinity of the AlInN based compound semiconductor reduces its spontaneous polarization. Deteriorating crystallinity of a portion of the second compound semiconductor layer 4 forms the third compound semiconductor layer 5 which has a lower spontaneous polarization than that of the second compound semiconductor layer 4. The lower spontaneous polarization may generate no two-dimensional electron gas layer or a second two-dimensional electron gas layer that has a lower concentration than that of the first two-dimensional electron gas layer. The first two-dimensional electron gas layer is adjacent to the first interface between the first and second compound semiconductor layers 3 and 4. The second two-dimensional electron gas layer is adjacent to the second interface between the first and third compound semiconductor layers 3 and 5. The second compound semiconductor layer 4 of AlInN based compound semiconductor may have spontaneous polarization that generates the two-dimensional electron gas layer 200 adjacent to the interface between the first and second compound semiconductor layers 3 and 4.

The second and third compound semiconductor layers 4 and 5 are disposed over the first compound semiconductor layer 3. In plan view, the second compound semiconductor layer 4 is disposed outside the third compound semiconductor layer 5. The third compound semiconductor layer 5 may have a thickness that is equal to or thicker than a total thickness of a few atomic layers. In some cases, the third compound semiconductor layer 5 may have a thickness in the range from 10 nanometers to 50 nanometers. The third compound semiconductor layer 5 may have almost the same thickness as the second compound semiconductor layer 4. The third compound semiconductor layer 5 may be made of the same compound semiconductor as the second compound semiconductor layer 4. The third compound semiconductor layer 5 has a lower crystallinity than that of the second compound semiconductor layer 4. The third compound semiconductor layer 5 is lower in spontaneous polarization and piezopolarization than the second compound semiconductor layer 4. The lower spontaneous polarization and piezopolarization may generate no two-dimensional electron gas layer or a second two-dimensional electron gas layer adjacent to the second interface between the first and third compound semiconductor layers 3 and 5. The second two-dimensional electron gas layer is lower in concentration than the first two-dimensional electron gas layer 200.

The third compound semiconductor layer 5 can be formed by ion-implantation or plasma irradiation to a portion of the second compound semiconductor layer 4. In some cases, ion species or ion source having volatility can be selected. The third compound semiconductor layer 5 can include volatile ions. Namely, the third compound semiconductor layer 5 can be formed of a volatile-ion-containing region of the second compound semiconductor layer 4. In other cases, ion species or ion source having non-volatility can be selected. The third compound semiconductor layer 5 can include non-volatile ions. Namely, the third compound semiconductor layer 5 can be formed of a volatile-ion-containing region of the second compound semiconductor layer 4.

Before forming the third compound semiconductor layer 5, the continuous coherent crystal structure is present over the first and second compound semiconductor layers 3 and 4. The lattice mismatch between the first and third compound semiconductor layers 3 and 5 introduces the strain into the crystal structure of the third compound semiconductor layer 5. The ion-implantation or plasma irradiation to a portion of the second compound semiconductor layer 4 changes the strained crystal structure of the third compound semiconductor layer 5 into the original crystal structure which has the original lattice pitch or relaxed crystal strain. The original crystal structure with the original lattice pitch has no strain. The third compound semiconductor layer 5 has no strain or lower strain of the crystal structure than the second compound semiconductor layer 4.

The third compound semiconductor layer 5 is lower in piezopolarization than the second compound semiconductor layer 4. No two-dimensional electron gas layer or a second two-dimensional electron gas layer is caused adjacent to the second interface between the first and third compound semiconductor layers 3 and 5. The second two-dimensional electron gas layer is lower in concentration than the first two-dimensional electron gas layer adjacent to the first interface between the first and second compound semiconductor layers 3 and 5.

The gate electrode 6 performing as a control gate is disposed over the third compound semiconductor layer 5. The gate electrode 6 may be formed of a conductive film such as an aluminum film or a polysilicon film. In some cases, the gate electrode 6 may be formed over the third compound semiconductor layer 5. In some modified cases, the transistor has the metal-insulator-semiconductor (MIS) structure.

FIG. 6 is a fragmentary cross sectional elevation view illustrating a high electron mobility transistor in a modification to the first embodiment of the present invention. An insulating film 12 is formed over the second and third compound semiconductor layers 4 and 5. The gate electrode 6 is disposed over the insulating film 12. The gate electrode 6 is separated by the insulating film 12 from the second and third compound semiconductor layers 4 and 5.

As shown in FIGS. 1 and 6, the source and drain electrodes 7 and 8 are disposed over the second compound semiconductor layer 4. The source and drain electrodes 7 and 8 are positioned both sides of the gate electrode 6. The source and drain electrodes 7 and 8 may have ohmic contact with the second compound semiconductor layer 4. The source and drain electrodes 7 and 8 may be formed by depositions of a titanium film over the second compound semiconductor layer 4 and an aluminum film over the titanium film.

As described above, the third compound semiconductor layer 5 causes no two-dimensional electron gas layer or a second two-dimensional electron gas layer adjacent to the second interface between the first and third compound semiconductor layer 5. No two-dimensional electron gas layer permits the high electron mobility transistor to perform the normally-off operation. The second two-dimensional electron gas layer permits the high electron mobility transistor to perform normally-on operation that is similar to the normally-off operation.

A negative voltage having a larger absolute value than the threshold is applied to the gate electrode 6 while a bias voltage being applied to between the source and drain electrodes 7 and 8, thereby concentrating electrons adjacent to the interface between the first and third compound semiconductor layers. Concentrating the electrons increases the concentration of the second two-dimensional electron gas layer up to similar or the same concentration of the first two-dimensional electron gas layer. Concentrating the electrons also generates the two-dimensional electron gas layer which has almost the same concentration as the first two-dimensional electron gas layer. As a result, the high electron mobility transistor turns ON.

The third compound semiconductor layer 5 is lower in crystallinity than the second compound semiconductor layer 4. In some cases, the third compound semiconductor layer 5 may have a polycrystalline structure. In other cases, the third compound semiconductor layer 5 may have an amorphous structure. In still other cases, the third compound semiconductor layer 5 may have a single crystal structure that contains a high density of defects.

FIG. 3 is a fragmentary cross sectional elevation view illustrating a high electron mobility transistor in a modification to the first embodiment of the present invention. The third compound semiconductor layer 5 does not contact with the first compound semiconductor layer 3. The third compound semiconductor layer 5 is positioned under the gate electrode 6. The third compound semiconductor layer 5 is separated from the first compound semiconductor layer 3 by a part of the second compound semiconductor layer 4. The second compound semiconductor layer 4 has first and second portions. The first portion is positioned under the third compound semiconductor layer 5 and over the first compound semiconductor layer 3. The first portion is positioned between the third compound semiconductor layer 5 and the first compound semiconductor layer 3. The second portion is the remaining portion of the first portion. The second portion extends over the first compound semiconductor layer 3 except under the third compound semiconductor layer 5.

The third compound semiconductor layer 5 has a smaller thickness than the second compound semiconductor layer 4. The top level of the third compound semiconductor layer 5 is the same as the top level of the second compound semiconductor layer 4. The bottom level of the third compound semiconductor layer 5 is above the bottom level of the second compound semiconductor layer 4. Namely, the third compound semiconductor layer 5 has a depth that is shallower than the bottom level of the second compound semiconductor layer 4.

The third compound semiconductor layer 5 is lower in piezopolarization than the second compound semiconductor layer 4. No two-dimensional electron gas layer or a second two-dimensional electron gas layer is caused adjacent to the interface between the first compound semiconductor layer 3 and the first portion of the second compound semiconductor layer 4. The second two-dimensional electron gas layer is lower in concentration than the first two-dimensional electron gas layer adjacent to the first interface between the first and second compound semiconductor layers 3 and 5. The third compound semiconductor layer 5 causes no two-dimensional electron gas layer or a second two-dimensional electron gas layer adjacent to the second interface between the first and third compound semiconductor layer 5. No two-dimensional electron gas layer permits the high electron mobility transistor to perform the normally-off operation. The second two-dimensional electron gas layer permits the high electron mobility transistor to perform normally-on operation that is similar to the normally-off operation.

The third compound semiconductor layer 5 can be formed by ion-implantation or plasma irradiation to a portion of the second compound semiconductor layer 4. The third compound semiconductor layer 5 is separated from the first compound semiconductor layer 3 by a part of the second compound semiconductor layer 4. The ion-implantation or plasma irradiation introduces damage to the portion of the second compound semiconductor layer 4, thereby forming the third compound semiconductor layer 5. No damage or a reduced damage does reach the interface between the first and second compound semiconductor layers 3 and 4. The damage is intended to be introduced to a shallower portion of the second compound semiconductor layer 4 than the interface between the first and second compound semiconductor layers 3 and 4. No damage or a reduced damage does reach the first portion of the second compound semiconductor layer 4, wherein the first portion is positioned under the third compound semiconductor layer 5. Highly crystallinity can be ensured over the first portion of the second compound semiconductor layer 4 and the first compound semiconductor layer 3. The two-dimensional electron gas is formed in the first compound semiconductor layer 3 and is adjacent to the interface between the first and second compound semiconductor layers 3 and 4. Thus, high electron mobility can be ensured for the high electron mobility transistor. The first compound semiconductor layer 3 that is shallower than the interface between the first and second compound semiconductor layers 3 and 4 can suppress the on-resistance of the high electron mobility transistor.

In the high electron mobility transistor shown in FIG. 3, the thickness of the third compound semiconductor layer 5 can be adjusted to adjust the pinch-off voltage thereof. As described above, the second compound semiconductor layer 4 has the first and second portions, wherein the first portion is positioned under the third compound semiconductor layer 5, and the second portion is the remaining portion thereof. In the third compound semiconductor layer 5, the first portion is thinner than the second portion.

As described above, the third compound semiconductor layer 5 can be formed by ion-implantation or plasma irradiation to a portion of the second compound semiconductor layer 4. In this case, the second and third compound semiconductor layers 4 and 5 are made of the same compound-semiconductor-based material. The combined structure of the second and third compound semiconductor layers 4 and 5 may form a compound semiconductor layered structure which has different crystallinity. The upper portion of the compound semiconductor layered structure has low or relaxed crystallinity as compared to the lower portion thereof. The compound semiconductor layered structure has such a crystallinity variation that the crystallinity increases as the position is closer to the interface with the first compound semiconductor layer 3.

As a further modification of the high electron mobility transistors shown in FIGS. 1 and 3, it is possible to further provide an additional insulating film between the first and second compound semiconductor layers 3 and 4. The additional insulating film can suppress the two-dimensional electron gas layer 200 from penetrating into the second compound semiconductor layer 4. The additional insulating film can suppress alloy diffusion. The additional insulating film can improve the mobility of the high electron mobility transistor. The additional insulating film may be made of, but is not limited to, AlN.

As a still further modification of the high electron mobility transistors shown in FIGS. 1 and 3, it is possible to further provide at least an additional compound semiconductor layer 11 between the second compound semiconductor layer 4 and the source electrode 7 or the drain electrode 8 or both. The additional compound semiconductor layer 11 may be made of, but is not limited to, GaN. The additional compound semiconductor layer 11 that is disposed between the second compound semiconductor layer 4 and the source electrode 7 can improve the contact characteristic between them. The additional compound semiconductor layer 11 that is disposed between the second compound semiconductor layer 4 and the drain electrode 8 can improve the contact characteristic between them.

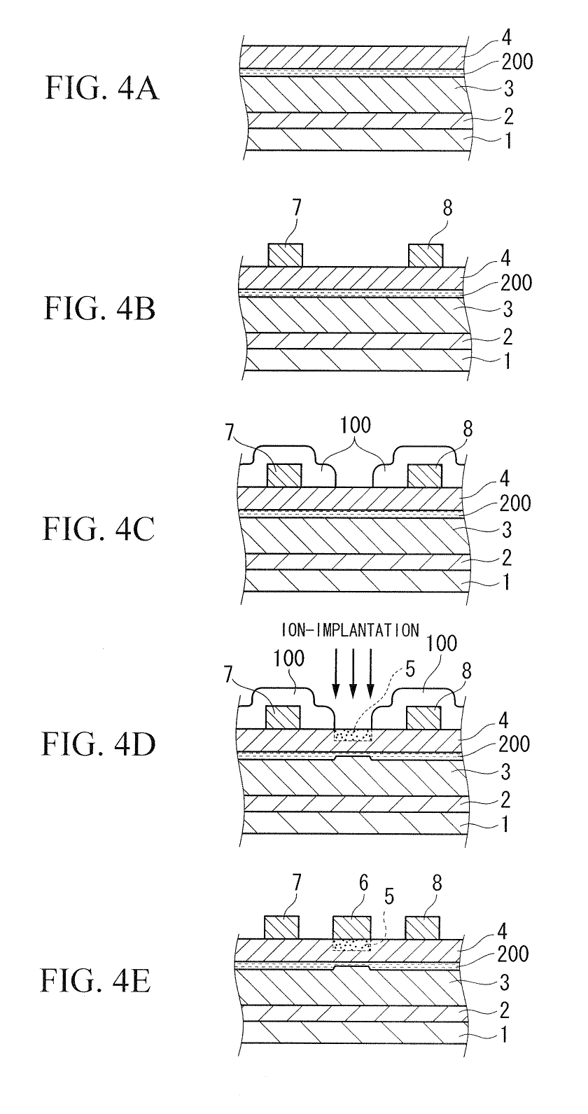

FIGS. 4A through 4E are fragmentary cross sectional elevation views illustrating sequential steps involved in a method of forming the high electron mobility transistor of FIG. 3.

As shown in FIG. 4A, a substrate 1 having a main surface 1a is prepared. A buffer layer 2 is formed over the main surface 1a of the substrate 1. A first compound semiconductor layer 3 is epitaxially grown over the buffer layer 2. A second compound semiconductor layer 4 is hetero-epitaxially grown over the first compound semiconductor layer 3.

As shown in FIG. 4B, a conductive material is formed over the second compound semiconductor layer 4 by a sputtering process or a vacuum deposition process. A resist film is applied over the conductive material. A lithography process is carried out to form a resist pattern over the conductive material. The conductive material is selectively removed using the resist pattern as a mask in a sputtering process or a vacuum evaporation process, thereby forming source and drain electrodes 7 and 8 over the second compound semiconductor layer 4. The used resist pattern is removed from the source and drain electrodes 7 and 8.

As shown in FIG. 4C, another resist film is applied over the second compound semiconductor layer 4 and the source and drain electrodes 7 and 8. Another lithography process is carried out to form another resist pattern 100 over the second compound semiconductor layer 4 and the source and drain electrodes 7 and 8, except over a selected area which is positioned between the source and drain electrodes 7 and 8.

As shown in FIG. 4D, an ion-implantation process or a plasma irradiation process is carried out using the resist pattern 100 as a mask, thereby forming a third compound semiconductor layer 5 in the second compound semiconductor layer 4. In the ion-implantation process or the plasma irradiation process, an inert gas or ions may be used. Typical examples of the inert gas may include, but are not limited to, argon (Ar), neon (Ne), and xenon (Xe). The ions can be selected from a material which can insulate a selected area of the second compound semiconductor layer 4.

A dry etching process will introduce crystal defects into a deep region of the second compound semiconductor layer 4. It is difficult for the dry etching process to accurately control the depth or thickness of the third compound semiconductor layer 5. It is easy for the ion-implantation process or the plasma irradiation process to control the depth of the implantation, thereby accurately controlling the crystallinity in the depth direction. The ion implantation has the high controllability. The thickness or depth of the third compound semiconductor layer 5 can be controlled by controlling the charges to be implanted and the acceleration voltage. In the ion-implantation process, the acceleration voltage and/or the kinds of ions may be selected depending upon the thicknesses and materials of the second and third compound semiconductor layers 4 and 5. In the plasma irradiation process, the bias voltage and/or the kinds of ions may be selected depending upon the thicknesses and materials of the second and third compound semiconductor layers 4 and 5.

As shown in FIG. 3, the thickness or depth of the third compound semiconductor layer 5 can be controlled so that the third compound semiconductor layer 5 does not reach the heterojunction interface between the first and second compound semiconductor layers 3 and 4. The third compound semiconductor layer 5 is thinner than the second compound semiconductor layer 4. The second compound semiconductor layer 4 has first and second portions. The first portion is positioned under the third compound semiconductor layer 5. The second portion is the remaining portion of the second compound semiconductor layer 4.

It is possible that the thickness or depth of the third compound semiconductor layer 5 can be controlled so that the third compound semiconductor layer 5 does reach the heterojunction interface between the first and second compound semiconductor layers 3 and 4. The third compound semiconductor layer 5 has the same thickness as that of the second compound semiconductor layer 4.

As shown in FIG. 4E, the resist pattern 100 is removed from the second compound semiconductor layer 4. A new resist film is applied over the second and third compound semiconductor layers 4 and 5 and the source and drain electrodes 7 and 8. A lithography process is carried out to form a resist pattern. The resist pattern covers the second compound semiconductor layer 4 and the source and drain electrodes 7 and 8. The resist pattern does not cover the third compound semiconductor layer 5. The resist pattern has an opening which is positioned over the third compound semiconductor layer 5. A conductive material is formed over the resist pattern and the third compound semiconductor layer 5 and in the opening of the resist pattern. A lift-off process is carried out to remove the conductive material over the resist pattern, while leaving the conductive material over the third compound semiconductor layer 5, thereby forming a gate electrode 6 over the third compound semiconductor layer 5.

In order to hold the lowered crystallinity or the relaxed crystal strain of the third compound semiconductor layer 5, a selective heat treatment is carried out to apply heat mainly to the second compound semiconductor layer 4, while no heat or smaller heat being applied to the third compound semiconductor layer 5. The selective heat treatment can be realized by, but is not limited to, a laser anneal process. It is possible as a modification to apply heat not only to the second compound semiconductor layer 4 but also to the third compound semiconductor layer 5 as long as the lower crystallinity or the relaxed crystal strain of the third compound semiconductor layer 5 is held.

The third compound semiconductor layer 5 has a thickness which is equal to or thicker than a few atomic layers. It is possible to avoid giving damage to the first compound semiconductor layer 3. This makes it possible to perform highly accurate control of the threshold voltage. This may improve the yield of the high electron mobility transistor. This may also improve the productivity.

In some cases, the second compound semiconductor layer 4 may be so thin that ions reach the first compound semiconductor layer 3 when the ions are implanted at the lowest energy. In order to solve the above-described issue, the following method of forming the transistor can be available.

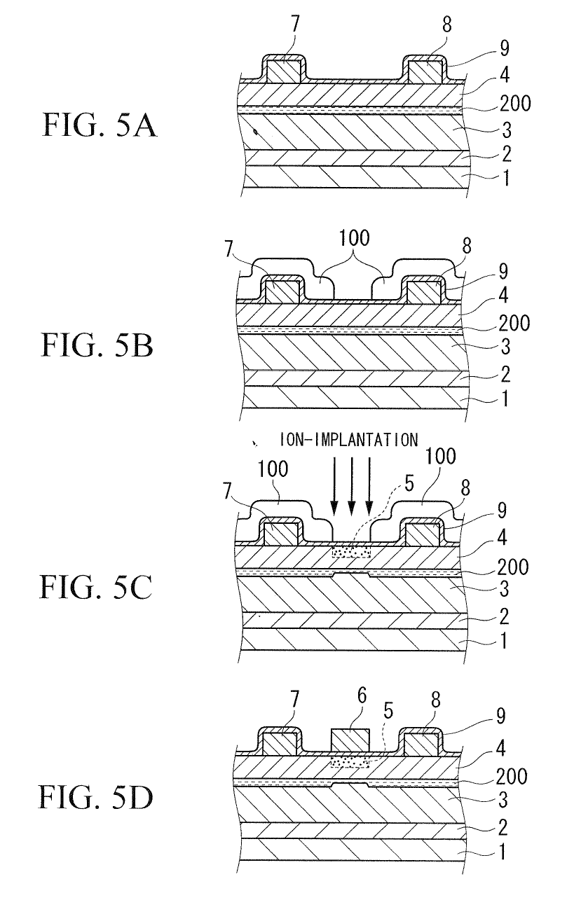

FIGS. 5A through 5D are fragmentary cross sectional elevation views illustrating sequential steps involved in another method of forming a modified high electron mobility transistor, wherein the sequential steps are subsequent to the step shown in FIG. 4B.

With reference again to FIG. 4A, a substrate 1 having a main surface 1a is prepared. A buffer layer 2 is formed over the main surface 1a of the substrate 1. A first compound semiconductor layer 3 is epitaxially grown over the buffer layer 2. A second compound semiconductor layer 4 is hetero-epitaxially grown over the first compound semiconductor layer 3.

With reference again to FIG. 4B, a conductive material is formed over the second compound semiconductor layer 4 by a sputtering process or a vacuum deposition process. A resist film is applied over the conductive material. A lithography process is carried out to form a resist pattern the conductive material. The conductive material is selectively removed using the resist pattern as a mask in a sputtering process or a vacuum evaporation process, thereby forming source and drain electrodes 7 and 8 over the second compound semiconductor layer 4. The used resist pattern is removed from the source and drain electrodes 7 and 8.

As shown in FIG. 5A, a thickness-controlling film 9 is formed over the source and drain electrodes 7 and 8 and the second compound semiconductor layer 4. The thickness-controlling film 9 can be formed by a sputtering process. The thickness-controlling film 9 may be formed of an oxide film.

As shown in FIG. 5B, a resist film is applied over almost the entirety of the thickness-controlling film 9. A lithography process is carried out to form a resist pattern 100.

As shown in FIG. 5C, an ion-implantation process or a plasma irradiation process is carried out using the resist pattern 100 as a mask, thereby forming a third compound semiconductor layer 5 in the second compound semiconductor layer 4. The ions penetrate through the thickness-controlling film 9 into a limited portion of the second compound semiconductor layer 4. The third compound semiconductor layer 5 is positioned under the thickness-controlling film 9. In the ion-implantation process or the plasma irradiation process, an inert gas or ions may be used. Typical examples of the inert gas may include, but are not limited to, argon (Ar), neon (Ne), and xenon (Xe). The ions can be selected from a material which can insulate a selected area of the second compound semiconductor layer 4.

As shown in FIG. 5D, the resist pattern 100 is removed from the thickness-controlling film 9. A new resist film is applied over the thickness-controlling film 9. A lithography process is carried out to form a resist pattern over the thickness-controlling film 9. The resist pattern has an opening which is positioned over a first portion of the thickness-controlling film 9, and the first portion is positioned over the third compound semiconductor layer 5. The resist pattern does not cover the first portion of the thickness-controlling film 9. A conductive material is formed over the resist pattern and the first portion of the thickness-controlling film 9 and in the opening of the resist pattern. A lift-off process is carried out to remove the conductive material over the resist pattern, while leaving the conductive material over the third compound semiconductor layer 5, thereby forming a gate electrode 6 over the first portion of the thickness-controlling film 9, wherein the first portion is positioned overt the third compound semiconductor layer 5.

The thickness or depth of the third compound semiconductor layer 5 can be adjusted by adjusting the thickness of the thickness-controlling film 9. Increasing the thickness of the thickness-controlling film 9 decreases the thickness or depth of the third compound semiconductor layer 5. It is easy to control the thickness of the thickness-controlling film 9 at a high accuracy. This means that it is possible to control the thickness of the third compound semiconductor layer 5 at a high accuracy by highly accurate controlling of the thickness-controlling film 9.

In some cases, the thickness-controlling film 9 can provide no damage to the crystal structure of the first portion of the second compound semiconductor layer 4, wherein the first portion is positioned over the third compound semiconductor layer 5. The thickness-controlling film 9 can also provide no damage to the heterojunction interface between the first and second compound semiconductor layers 3 and 4. The thickness-controlling film 9 can also provide no damage to the crystal structure of the first compound semiconductor layer 3.

In other cases, the thickness-controlling film 9 can reduce the damage to the crystal structure of the first portion of the second compound semiconductor layer 4, wherein the first portion is positioned over the third compound semiconductor layer 5. The thickness-controlling film 9 can also reduce the damage to the heterojunction interface between the first and second compound semiconductor layers 3 and 4. The thickness-controlling film 9 can also reduce the damage to the crystal structure of the first compound semiconductor layer 3.

With reference again to FIG. 6, the high electron mobility transistor can be modified to have a metal-insulator-semiconductor gate structure. The high electron mobility transistor can further include an insulating film that is formed over the second and third compound semiconductor layers 4 and 5. The gate electrode 6 is disposed over the insulating film 12. The gate electrode 6 is separated by the insulating film from the second and third compound semiconductor layers 4 and 5.

The high electron mobility transistor can be formed as follows. The same processes as described with reference to FIGS. 4A through 4D are carried out. After the third compound semiconductor layer 5 is formed, an oxide film 12 is formed over the second and third compound semiconductor layers 4 and 5. The oxide film 12 may be formed by a sputtering process. The oxide film 12 has a first portion which is positioned over the third compound semiconductor layer 5. A resist film is applied over the oxide film. A lithography process is carried out to form a resist pattern which has an opening that is positioned over the first portion of the oxide film 12, wherein the first portion of the oxide film 12 is positioned over the third compound semiconductor layer 5.

A conductive film is formed over the resist pattern and the first portion of the oxide film 12 by a sputtering process. A lift-off process is carried out to remove the conductive film over the resist pattern, while leaving the conductive film over the first portion of the oxide film 12, thereby forming a gate electrode 6 over the first portion of the oxide film 12, which is positioned over the third compound semiconductor layer 5. The first portion of the oxide film 12 is positioned under the gate electrode 6 and over the third compound semiconductor layer 5. The oxide film 12 is disposed between the gate electrode 6 and the third compound semiconductor layer 5. The oxide film 12 can suppress the leakage of current between the gate electrode 6 and the electron traveling layer 3.

In accordance with the high electron mobility transistors shown in FIGS. 1, 3 and 6, the third compound semiconductor layer 5 extends under the entirety of the gate electrode 6. Namely, the edges of the third compound semiconductor layer 5 are aligned in plan view to the edges of the gate electrode 6. It is possible as a modification that the third compound semiconductor layer 5 is present under at least a part of the gate electrode 6. For example, the third compound semiconductor layer 5 can be modified to extend under a part of the gate electrode 6.

The third compound semiconductor layer 5 may be made of the same semiconductor material as the second compound semiconductor layer 4.

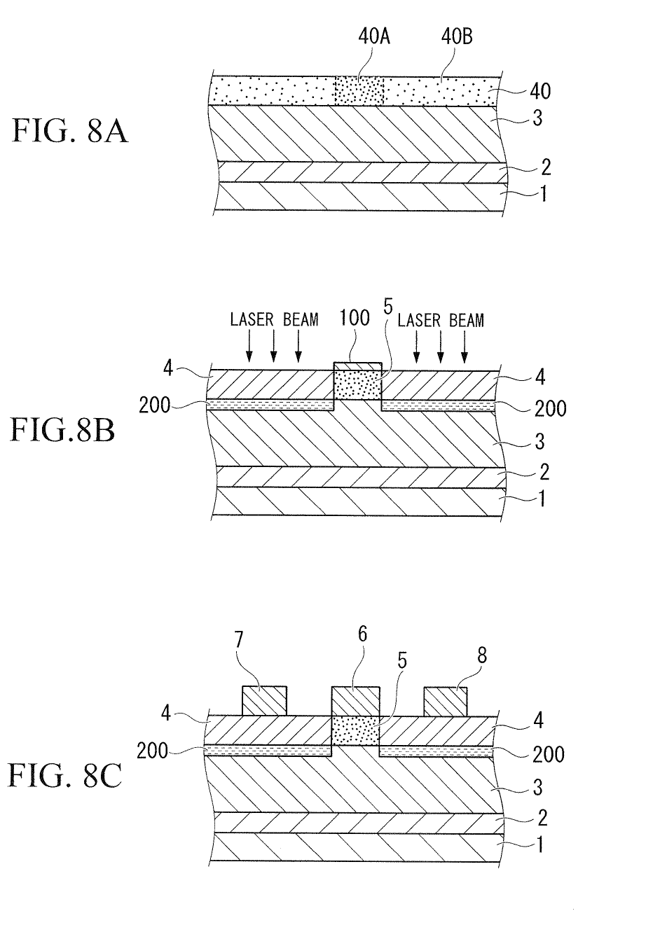

FIGS. 8A through 8C are fragmentary cross sectional elevation views illustrating sequential steps involved in a method of forming the high electron mobility transistor shown in FIG. 1.

As shown in FIG. 8A, a substrate 1 with a main surface 1a is prepared. A buffer layer 2 is formed over the main surface 1a of the substrate 1. A first compound semiconductor layer 3 is epitaxially grown over the buffer layer 2. A fifth compound semiconductor layer 40 is hetero-epitaxially grown over the first compound semiconductor layer 3, thereby forming a heterojunction interface between the first and fifth compound semiconductor layers 3 and 40. In some cases, the first compound semiconductor layer 3 may be made of GaN. The GaN compound semiconductor layer 3 may be formed at a temperature range of 900° C. to 1200° C. The fifth compound semiconductor layer 40 may be formed at a lower temperature than the temperature at which the first compound semiconductor layer 3 is formed. The lower temperature is such a temperature that the fifth compound semiconductor layer 40 has amorphous or microcrystal structure with no or almost no single crystal structure. The fifth compound semiconductor layer 40 has lowered crystallinity or relaxed crystal strain. The fifth compound semiconductor layer 40 may be made of, but is not limited to, AlₓIn_{y}Ga_{1-x-y}N (0≦x≦1, 0≦y≦1, 0≦x+y≦1). A typical example of the lower temperature at which the fifth compound semiconductor layer 40 is formed may be, but is not limited to, 500° C. In a typical example, the fifth compound semiconductor layer 40 of AlₓIn_{y}Ga_{1-x-y}N may be formed at 500° C. over the first compound semiconductor layer 3 of GaN.

The fifth compound semiconductor layer 40 has lowered crystallinity or relaxed crystal strain. Lowering the crystallinity or relaxation of the crystal strain may cause a spontaneous polarization. A piezopolarization may be caused between the first and fifth compound semiconductor layers 3 and 40. An electric field is generated by the spontaneous polarization and the piezopolarization. The electric field is so weak as to cause no two-dimensional electron gas layer or a reduced two-dimensional electron gas layer that is adjacent to the interface between the first and fifth compound semiconductor layers 3 and 40. The reduced two-dimensional electron gas layer has a reduced concentration and a reduced thickness. The fifth compound semiconductor layer 40 has a first portion 40A over which a gate electrode will be formed in the later process and a second portion 40B as the remaining portion.

As shown in FIG. 8B, the second portion 40B of the fifth compound semiconductor layer 40 is annealed to selectively crystallize the second portion 40B of the fifth compound semiconductor layer 40, while causing no or almost no crystallization of the first portion 40A. The second portion 40B of the fifth compound semiconductor layer 40 is crystallized to have a single crystal structure, while the first portion 40A may generally have lower crystallinity or more relaxed crystal strain as compared to the second portion 40B. The selective anneal mainly to the second portion 40B may makes the first and second portions 40A and 40B into third and second compound semiconductor layers 5 and 4, respectively. In typical case, the second portion 40B is annealed and crystallized, and the second portion 40B becomes the second compound semiconductor layer 4 that has the single crystal structure. The first portion 40A is not annealed or weaker annealed as compared to the second portion 40B. The first portion 40A becomes the third compound semiconductor layer 5 that has lower crystallinity or more relaxed crystal stain as compared to the second portion 40B.

In some cases, the annealing process may be realized by, but is not limited to, a laser anneal process. A mask 100 is selectively formed which covers the first portion 40A of the fifth compound semiconductor layer 40. A laser beam is selectively irradiated onto the second portion 40B of the fifth compound semiconductor layer 40, while the mask 100 shields the first portion 40A from the laser beam irradiation, thereby selectively or mainly annealing the second portion 40B of the fifth compound semiconductor layer 40. In other cases, the annealing process may also be realized by, but is not limited to, an electron beam irradiation process.

The crystallization of the second portion 40B of the fifth compound semiconductor layer 40 can increase the spontaneous polarization and the piezopolarization. Namely, the annealing process can increase the spontaneous polarization and the piezopolarization, thereby increasing the electric field. The increased electric field may generate a two-dimensional electron gas 200 that is adjacent to the interface between the first and second compound semiconductor layers 3 and 4.

The lowered crystallinity or the relaxed crystal strain of the first portion 40A of the fifth compound semiconductor layer 40 may cause no or almost no increase of the lower spontaneous polarization and piezopolarization, thereby keeping the lower electric field. The lower electric field may generate no two-dimensional electron gas layer or a reduced two-dimensional electron gas layer that is adjacent to the interface between the first and third compound semiconductor layers 3 and 5. The reduced two-dimensional electron gas layer has a reduced concentration and/or a reduced thickness. The reduced two-dimensional electron gas layer that is adjacent to the interface between the first and third compound semiconductor layers 3 and 5 is lower in concentration and thickness than the two-dimensional electron gas layer 200 adjacent to the interface between the first and second compound semiconductor layers 3 and 4. The two-dimensional electron gas layer 200 does not extend substantially under the third compound semiconductor layer 5.

As shown in FIG. 8C, after the mask 100 is removed, a conductive material may be formed over the second and third compound semiconductor layers 4 and 5 by a sputtering process or a vacuum deposition process. A resist film is applied over the conductive material. A lithography process is carried out to form a resist pattern. The resist pattern is used as a mask to carry out a sputtering process or a vacuum evaporation process, thereby selectively removing the conductive material, and forming gate, source and drain electrodes 6, 7 and 8. The gate electrode 6 is positioned over the third compound semiconductor layer 5. The source and drain electrodes 7 and 8 are positioned over the second compound semiconductor layer 4. The resist pattern is removed.

The above-described laser annealing process for crystallizing the second portion 40B of the fifth compound semiconductor layer 40 can be realized as follows. Typical examples of the light source that emits a laser beam may include, but are not limited to, a low pressure mercury lamp, a high pressure mercury lamp, an ultra-high pressure mercury lamp, a zinc pump, a halogen lamp, an excimer lamp, and a xenon lamp. It is also possible to use the fundamental wave of a laser, or light that is obtained by non-linear optical effect of the fundamental wave of a laser. Typical examples of the laser may include, but are not limited to, an excimer laser, an argon ion laser, a krypton ion laser, an Nd:YVO4 laser, an Nd:YAG laser, an Nd:YLF laser, a Ti: sapphire laser, semiconductor lasers, and dye lasers.

In some preferable cases, when the light is irradiated to the fifth compound semiconductor layer 40, the light is strongly absorbed into the fifth compound semiconductor layer 40 and the light is converted into thermal energy. The wavelength of the light may be preferably in the ultraviolet region or near ultraviolet region. The light having the harmonic wave may be preferable. Thus, it is more preferable to use the harmonic wave light of the excimer laser, the argon ion laser, and the Nd:YAG laser which have wavelengths in the ultraviolet region or near ultraviolet region.

When the fifth compound semiconductor layer 40 is thin, the excimer laser is preferable due to its short wavelength. When the fifth compound semiconductor layer 40 is thick, the Nd:YAG laser is preferable due to its long wavelength. In general, the laser beam of a wavelength of at most 600 nm may satisfy the above-described conditions.

The laser beam irradiation process can be carried out by keeping the fifth compound semiconductor layer 40 in the range of about room temperature, for example, 25° C. to about 400° C. and in a nitrogen atmosphere.

A pulse laser can be irradiated to the fifth compound semiconductor layer 40, whereby the absorbed light energy is converted into thermal energy and a rapid temperature increase is caused. The pulse width of the pulse laser may be preferably at most 500 nm. The heat that is generated upon the pulse laser irradiation is diffused rapidly, whereby the fifth compound semiconductor layer 40 is cooled rapidly. When the energy given by the laser beam irradiation is enough to melt the fifth compound semiconductor layer 40, then the second portion 40B of the fifth compound semiconductor layer 40 is melt, and then the second portion 40B is single-crystallized in the cooling process. Increased energy of the laser beam irradiation increases the depth of a melt portion of the second portion 40B of the fifth compound semiconductor layer 40. The energy of the laser beam irradiation should be adjusted to avoid that the second portion 40B of the fifth compound semiconductor layer 40 is completely melt.

The method shown in FIGS. 8A through 8C does not need the laser annealing process shown in FIG. 4E. The method shown in FIGS. 8A through 8C can form the gate, source and drain electrodes 6, 7 and 8 in the common process. The method shown in FIGS. 8A through 8C can form the same high electron mobility transistor structure of FIG. 1 by the reduced number of processes and at a lower manufacturing cost as compared top the method of FIGS. 4A through 4E.

In the foregoing embodiments, the two-dimensional carrier gas is the two-dimensional electron gas 200. The above-described embodiments can be applied to a high electron mobility transistor that has a two-dimensional hole gas that is adjacent to the interface between the first and second compound semiconductor layers 3 and 4.

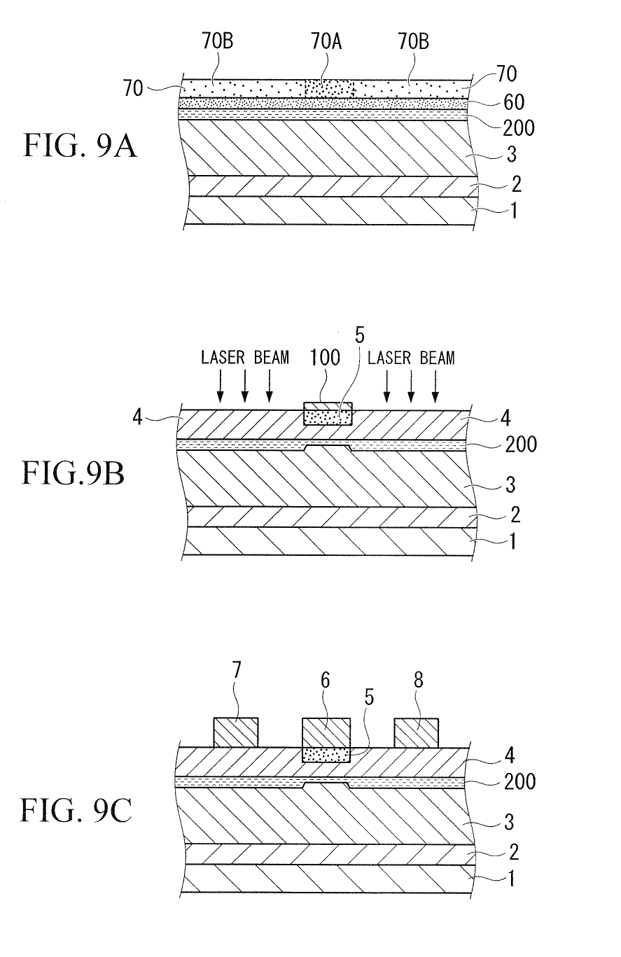

FIGS. 9A through 9C are fragmentary cross sectional elevation views illustrating sequential steps involved in another method of forming the high electron mobility transistor shown in FIG. 3.

As shown in FIG. 9A, a substrate 1 with a main surface 1a is prepared. A buffer layer 2 is formed over the main surface 1a of the substrate 1. A first compound semiconductor layer 3 is epitaxially grown over the buffer layer 2. In some cases, the first compound semiconductor layer 3 may be made of GaN. The GaN compound semiconductor layer 3 may be formed in a temperature range of 900° C. to 1200° C. A sixth compound semiconductor layer 60 is hetero-epitaxially grown over the first compound semiconductor layer 3 in the temperature range of 900° C. to 1200° C., thereby forming a heterojunction interface between the first and fifth compound semiconductor layers 3 and 60. The sixth compound semiconductor layer 60 may have a thickness in the range of 5 nanometers to 10 nanometers. The sixth compound semiconductor layer 60 may be made of, but is not limited to, AlₓIn_{y}Ga_{1-x-y}N (0≦x≦1, 0≦y≦1, 0≦x+y≦1). The sixth compound semiconductor layer 60 have a single crystal structure that is lattice-matched to the single crystal structure of the first compound semiconductor layer 3 of GaN. Thus, a two-dimensional electron gas layer 200 is generated which is adjacent to the interface between the first and fifth compound semiconductor layers 3 and 60.

The spontaneous polarization of the sixth compound semiconductor layer 60 and the piezopolarization between the first and fifth compound semiconductor layers 3 and 60 can be adjusted by adjusting the thickness of the compound semiconductor layers 3 and 60. The concentration of the two-dimensional electron gas layer 200 that is generated adjacent to the interface between the first and fifth compound semiconductor layers 3 and 60 can be adjusted by adjusting the spontaneous polarization and the piezopolarization. Thus, the concentration of the two-dimensional electron gas layer 200 can be adjusted by adjusting the thickness of the compound semiconductor layers 3 and 60.

A seventh compound semiconductor layer 70 is epitaxially grown over the sixth compound semiconductor layer 60, thereby forming an interface between the fifth and sixth compound semiconductor layers 60 and 70. The seventh compound semiconductor layer 70 may be formed at a lower temperature than the temperature at which the sixth compound semiconductor layer 60 is formed. The lower temperature is such a temperature that the seventh compound semiconductor layer 70 has amorphous or microcrystal structure with no or almost no single crystal structure. The seventh compound semiconductor layer 70 has lowered crystallinity or relaxed crystal strain. The seventh compound semiconductor layer 70 may be made of, but is not limited to, AlₓIn_{y}Ga_{1-x-y}N (0≦x≦1, 0≦y≦1, 0≦x+y≦1). A typical example of the lower temperature at which the seventh compound semiconductor layer 70 is formed may be, but is not limited to, 500° C. In a typical example, the seventh compound semiconductor layer 70 of AlₓIn_{y}Ga_{1-x-y}N may be formed at 500° C. over the sixth compound semiconductor layer 60 of AlₓIn_{y}Ga_{1-x-y}N. The thickness of the seventh compound semiconductor layer 70 may be in the range of 10 nm to 20 nm.

The seventh compound semiconductor layer 70 has a first portion 70A over which a gate electrode will be formed in the later process and a second portion 70B as the remaining portion. The sixth compound semiconductor layer 60 has a first portion under the first portion 70A and a second portion under the second portion 70B.

As shown in FIG. 9B, the second portion 90B of the seventh compound semiconductor layer 70 is annealed to selectively crystallize the second portion 70B of the seventh compound semiconductor layer 70, while causing no or almost no crystallization of the first portion 70A. In typical case, the second portion 70B of the seventh compound semiconductor layer 70 may be crystallized to have a single crystal structure, while the first portion 70A may have lower crystallinity or more relaxed crystal strain as compared to the second portion 70B. The sixth compound semiconductor layer 60 may still have the single crystal structure. Namely, the single-crystallized second portion 70B of the seventh compound semiconductor layer 70 and the sixth compound semiconductor layer 60 both have the single crystal structure of AlₓIn_{y}Ga_{1-x-y}N.

The selective anneal mainly to the second portion 70B of the seventh compound semiconductor layer 70 may make both the second portion 70B of the seventh compound semiconductor layer 70 and the sixth compound semiconductor layer 60 into the second compound semiconductor layer 4 which has the single crystal structure, while the first portion 70A of the seventh compound semiconductor layer 70 becomes the third compound semiconductor layer 5 which still has the lower crystallinity or more relaxed crystal strain. The selective anneal mainly to the second portion 70B of the seventh compound semiconductor layer 70 may make the first and second portions 70A and 70B into the third compound semiconductor layer 5 and a part of the second portion of the second compound semiconductor layer 4, respectively. The selective annealing also may make the first and second portions of the sixth compound semiconductor layer 60 into the first portion and the remaining part of the second portion of the second compound semiconductor layer 4, respectively. The second compound semiconductor layer 4 includes first and second portion, wherein the first portion is positioned under the third compound semiconductor layer 5 and the second portion is the remaining portion.

In some cases, the annealing process may be realized by, but is not limited to, a laser annealing process. A mask 100 is selectively formed which covers the first portion 70A of the seventh compound semiconductor layer 70. A laser beam is selectively irradiated onto the second portion 70B of the seventh compound semiconductor layer 70, while the mask 100 shields the first portion 70A from the laser beam irradiation, thereby selectively or mainly annealing the second portion 70B of the seventh compound semiconductor layer 70. In other cases, the annealing process may also be realized by, but is not limited to, an electron beam irradiation process.

The crystallization of the second portion 70B of the seventh compound semiconductor layer 70 can increase the spontaneous polarization and the piezopolarization. Namely, the annealing process can increase the spontaneous polarization and the piezopolarization, thereby increasing the electric field. The increased electric field may generate a two-dimensional electron gas 200 that is adjacent to the interface between the first and second compound semiconductor layers 3 and 4.

The lowered crystallinity or the relaxed crystal strain of the first portion 70A of the seventh compound semiconductor layer 70 may cause no or almost no increase of the lower spontaneous polarization and piezopolarization, thereby keeping the lower electric field. The lower electric field may generate no two-dimensional electron gas layer or a reduced two-dimensional electron gas layer that is adjacent to the interface between the first compound semiconductor layer 3 and the first portion of the second compound semiconductor layer 4. The reduced two-dimensional electron gas layer has a reduced concentration and a reduced thickness. The reduced two-dimensional electron gas layer that is adjacent to the interface between the first compound semiconductor layer 3 and the first portion of the second compound semiconductor layer 4 is lower in concentration and thickness than the two-dimensional electron gas layer 200 adjacent to the interface between the first compound semiconductor layer 3 and the second portion of the second compound semiconductor layer 4.

The fifth and sixth compound semiconductor layers 60 and 70 may have the same compound semiconductor of the same single crystal structure.

The method of locally annealing the second portion 70B of the seventh compound semiconductor layer 70 can be realized by, but not limited to, the laser annealing method.

As shown in FIG. 9C, after the mask 100 is removed, a conductive material is formed over the second and third compound semiconductor layers 4 and 5 by a sputtering process or a vacuum deposition process. A resist film is applied over the conductive material. A lithography process is carried out to form a resist pattern. The resist pattern is used as a mask to carry out a sputtering process or a vacuum evaporation process, thereby selectively removing the conductive material, and forming gate, source and drain electrodes 6, 7 and 8. The gate electrode 6 is positioned over the third compound semiconductor layer 5. The source and drain electrodes 7 and 8 are positioned over the second compound semiconductor layer 4. The resist pattern is removed.

The transistor shown in FIG. 9C can provide the same effects as those of the transistor shown in FIG. 3. The lowered crystallinity or the relaxed crystal strain of the first portion 70A of the seventh compound semiconductor layer 70 may cause no or almost no increase of the lower spontaneous polarization and piezopolarization, thereby keeping the lower electric field. The lower electric field may generate no two-dimensional electron gas layer or a reduced two-dimensional electron gas layer that is adjacent to the interface between the first compound semiconductor layer 3 and the first portion of the second compound semiconductor layer 4. The reduced two-dimensional electron gas layer has a reduced concentration and a reduced thickness. The reduced two-dimensional electron gas layer that is adjacent to the interface between the first compound semiconductor layer 3 and the first portion of the second compound semiconductor layer 4 is lower in concentration and thickness than the two-dimensional electron gas layer 200 adjacent to the interface between the first compound semiconductor layer 3 and the second portion of the second compound semiconductor layer 4.

In the foregoing embodiments, the two-dimensional carrier gas is the two-dimensional electron gas 200. The above-described embodiments can be applied to a high electron mobility transistor that has a two-dimensional hole gas that is adjacent to the interface between the first and second compound semiconductor layers 3 and 4.

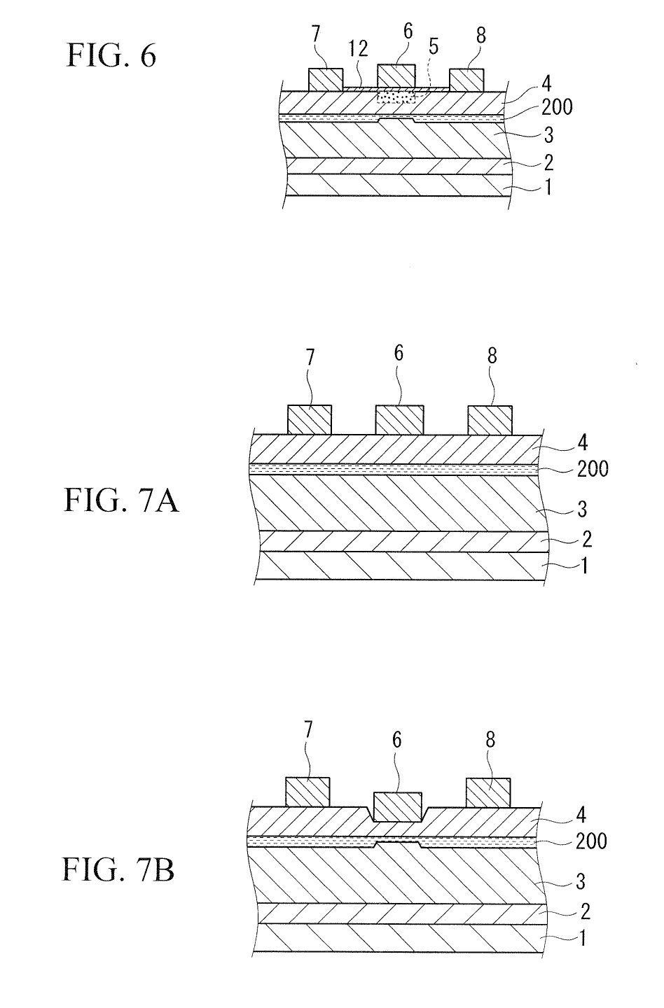

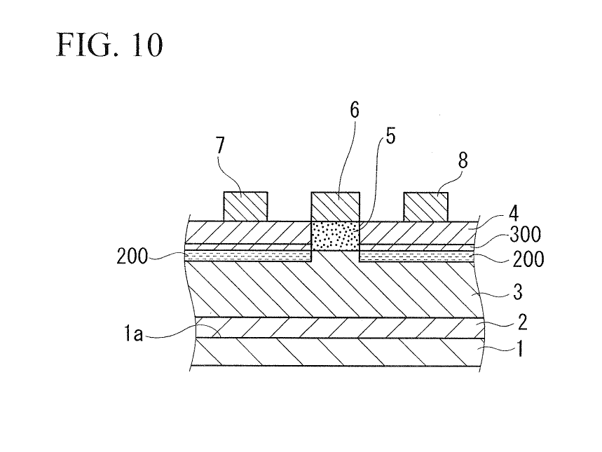

FIG. 10 is a fragmentary cross sectional elevation view illustrating a high electron mobility transistor in accordance with a further modification to the first embodiment of the present invention. In the foregoing embodiments shown in FIGS. 1-9C, the second compound semiconductor layer has the heterojunction interface with the first compound semiconductor layer 3. It is possible as a further modification to insert a fourth compound semiconductor layer 300 between the first and second compound semiconductor layers 3 and 4 as shown in FIG. 10. The fourth compound semiconductor layer 300 is absent under the gate electrode 6. In other words, the fourth compound semiconductor layer 300 has a heterojunction interface with the first compound semiconductor layer 3, and the third compound semiconductor layer 5 also has another heterojunction interface with the first compound semiconductor layer 3. Namely, the first compound semiconductor layer 3 contacts with the third and fourth compound semiconductor layers 5 and 300. The second compound semiconductor layer 4 is separated by the fourth compound semiconductor layer 300 from the first compound semiconductor layer 3.

The fourth compound semiconductor layer 300 is wider in band gap than the first and second compound semiconductor layers 3 and 4. In one typical case, the first and second compound semiconductor layers 3 and 4 may comprise GaN and AlGaN, respectively, and the fourth compound semiconductor layer 300 may comprise AlN. The fourth compound semiconductor layer 300 increases at least one of the concentration and the thickness of the two-dimensional electron gas layer 200 because the fourth compound semiconductor layer 300 is wider in band gap than the first and second compound semiconductor layers 3 and 4.

The fourth compound semiconductor layer 300 may perform as a spacer layer which prevents impurity and/or element in the second compound semiconductor layer 4 from being diffused into the first compound semiconductor layer 3, thereby preventing the mobility of electrons from being lowered.

It is further possible as moreover modification that the fourth compound semiconductor layer 300 can be inserted into between the first and second compound semiconductor layers 3 and 4 except under the gate electrode 6 in the high electron mobility transistors in the foregoing embodiments. The fourth compound semiconductor layer 300 increases at least one of the concentration and the thickness of the two-dimensional electron gas layer 200 because the fourth compound semiconductor layer 300 is wider in band gap than the first and second compound semiconductor layers 3 and 4. The fourth compound semiconductor layer 300 can also perform as the spacer layer which prevents impurity and/or element in the second compound semiconductor layer 4 from being diffused into the first compound semiconductor layer 3, thereby preventing the mobility of electrons from being lowered.

The two-dimensional carrier gas layer may be classified into a two-dimensional electron gas layer and a two-dimensional hole gas layer. In the foregoing embodiments, the two-dimensional electron gas layer is used as an example of the two-dimensional carrier gas layer. The two-dimensional electron gas layer can be replaceable by the two-dimensional hole gas layer. The above-described embodiments can be applied to a high electron mobility transistor that has a two-dimensional hole gas layer instead of the two-dimensional electron gas layer.

As used herein, the following directional terms “over, under, forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. A high electron mobility transistor comprising:
a first compound semiconductor layer having first and second faces;
a second compound semiconductor layer disposed over the first compound semiconductor layer, the second compound semiconductor layer being closer to the first face than the second face;
a third compound semiconductor layer disposed over the first compound semiconductor layer, the third compound semiconductor layer having at least one of lower crystallinity and more relaxed crystal strain as compared to the second compound semiconductor layer;
a gate electrode disposed over the third compound semiconductor layer; and
a two-dimensional carrier gas layer in the first compound semiconductor layer, the two-dimensional carrier gas layer being adjacent to the first face, the two-dimensional carrier gas layer either being absent under the third compound semiconductor layer or being reduced in at least one of thickness and carrier gas concentration under the third compound semiconductor layer, wherein the third compound semiconductor layer is separated by the second compound semiconductor layer from the first compound semiconductor layer.

2. The high electron mobility transistor according to claim 1, wherein the second compound semiconductor layer has a first heterojunction interface with the first compound semiconductor layer.

3-7. (canceled)

8. The high electron mobility transistor according to claim 1, wherein the second compound semiconductor layer has a first portion and a second portion, the first portion is positioned under the third compound semiconductor layer and over the first compound semiconductor layer, the first portion is thinner than the second portion.

9. The high electron mobility transistor according to claim 1, wherein the third compound semiconductor layer comprises compound elements of the second compound semiconductor layer.

10-31. (canceled)

32. The high electron mobility transistor according to claim 8, wherein the third compound semiconductor layer comprises compound elements of the second compound semiconductor layer.
